(19) United States
(12) Patent Application Publication
(10) Pub. No.: US 2008/0182415 A1
(43) Pub. Date: Jul. 31, 2008

(54) SEMICONDUCTOR DEVICE AND METHOD FOR FABRICATING THE SAME

(75) Inventors: Sung Mok HONG, Gyeonggi-do (KR); Kew Chan SHIM, Gyeonggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/770,186

(22) Filed: Jun. 28, 2007

(30) Foreign Application Priority Data
Jan. 26, 2007 (KR) 10-2007-0008327

(51) Int. Cl. H01L 21/311; G03F 1/00

(52) U.S. Cl. 438/703; 430/270.1; 430/5; 257/E21.023

(57) ABSTRACT

A semiconductor device comprises a semiconductor substrate including a scribe lane, and a metal layer disposed over the semiconductor substrate. The metal layer is formed over the overlay vernier by a sputtering method. The overlay vernier comprises a bar type mother vernier formed in the scribe lane. The overlay vernier has a sloped profile.

### CROSS-REFERENCES TO RELATED APPLICATIONS

Priority to Korean patent application number 10-2007-0008327, filed on Jan. 26, 2007, the disclosure of which is incorporated by reference in its entirety, is claimed.

### BACKGROUND OF THE INVENTION

The present invention relates to a semiconductor device. More particularly, the present invention relates to a semiconductor device including a metal layer formed using a sloped sidewall overlay vernier and a method for fabricating the same.

A photolithography process includes coating a photoresist film over a wafer. An exposing and developing process is performed to form a mask. The photolithography process is performed before an etching process and an ion-implanting process that require a mask. A process for manufacturing an integrated device includes forming a multi-layered pattern using the photolithography process. As a result, multi-layered patterns (e.g., upper and lower layers) are required to be accurately arranged. The photolithography process is performed to form a given pattern on each layer including an insulating layer and a conductive layer over a wafer. The photolithography process is performed using a light source and a pattern transcriber such as a mask or a reticle. In the photolithography process, patterns formed in one step and a pattern to be formed in a subsequent step are required to be accurately arranged to produce a reliable semiconductor circuit.

The overlay accuracy represents the state of alignment between patterns of upper and lower layers formed in the photolithography. The overlay accuracy is used as an important variable. Also, the overlay accuracy is measured using an overlay vernier formed in a scribe lane of a wafer. The overlay vernier includes a mother vernier formed as a lower layer and a child vernier formed as an upper layer. That is, while a given pattern of the lower layer is formed in a die region of the wafer, the mother vernier is formed in the scribe lane. Then while the upper layer of the given pattern is formed over the lower layer in the die region, the child vernier is formed in the scribe lane so that when the two layers are aligned the child vernier is inside the mother vernier when viewed from above.

When a metal layer is deposited using a sputtering apparatus, the sputtering apparatus causes an asymmetric deposition, which results in an overlay misreading. The asymmetric deposition is caused in the sputtering apparatus because of irregular orientation of an electric field applied between a sputtering target and a wafer. Specifically, the irregular orientation of the electric field is shown to be more intense at the outside than at the center of the wafer so that patterns formed at the outside of the wafer tend to be more less uniform than those formed proximate the center of the wafer. Also, since the asymmetric deposition (e.g., non-uniformity in thickness of the layer deposited) is disposed over the mother vernier, the position of the mother vernier is distorted. As a result, the asymmetric deposition may cause overlay mis-measurement.

### BRIEF SUMMARY OF THE INVENTION

Embodiments of the present invention relate to a semiconductor device including a metal layer. According to one embodiment of the invention, the metal layer is formed using an overlay vernier having a sloped sidewall.

According to an embodiment of the present invention, an overlay vernier mask having a Box-in-Bar type overlay vernier mask comprises a transparent substrate, a bar type mother vernier pattern disposed over the transparent substrate, and a plurality of dummy patterns disposed adjacent to the mother vernier pattern to disperse intensity of exposure light.

The plurality of dummy patterns are bar-type patterns formed on both sides of the mother vernier pattern along the minor axis of the mother vernier pattern. A line width D of the plurality of dummy patterns formed on one side of the mother vernier pattern is in a range of about 0.15˜0.35 of the line width M of the mother veriner pattern (0.15M≦D≦0.35M). A line width L of the dummy pattern is in a range of about 0.01˜0.02 of the line width M of the mother vernier pattern (0.15M≦L≦0.35M).

According to an embodiment of the present invention, an overlay vernier having a Box-in-Bar type overlay vernier comprises a semiconductor substrate including a scribe lane, and a bar-type mother vernier formed in the scribe lane. The mother vernier has a sloped profile. A sloped angle of the mother vernier is in a range of about 30˜60°.

According to an embodiment of the present invention, a method for forming an overlay vernier having a Box-in-Bar type overlay vernier comprises: providing a semiconductor substrate including a scribe lane; forming a photoresist film over the semiconductor substrate; exposing the photoresist film by using an overlay vernier mask including a plurality of dummy patterns to form a photoresist pattern having a sloped profile; and etching the semiconductor substrate in the scribe lane by using the photoresist pattern as an etching mask to form a mother vernier having a sloped profile. A sloped angle of the mother vernier is in a range of about 30˜60°.

According to an embodiment of the present invention, a semiconductor device comprises a semiconductor substrate including a scribe lane, and a metal layer disposed over the semiconductor substrate. The metal layer is formed by a sputtering method. The overlay vernier comprises a bar type mother vernier formed in the scribe lane, the mother vernier having a sloped profile.

According to an embodiment of the present invention, a method for fabricating a semiconductor device comprises: providing a semiconductor substrate including a scribe lane; forming a photoresist film over the semiconductor substrate; exposing the photoresist film by using an overlay vernier mask including a plurality of dummy patterns to form a photoresist pattern having a sloped profile; etching the semiconductor substrate in the scribe lane by using the photoresist pattern as an etching mask to form a mother vernier having a sloped profile; removing the photoresist pattern; and performing a sputtering process to form a metal layer over the mother vernier of the semiconductor substrate.

In one embodiment, an overlay vernier mask comprises a transparent substrate. A bar-type mother vernier pattern is disposed over the transparent substrate, the mother vernier pattern defining a first side and a second side, the first side being on an opposing side of the second side. A first plurality of dummy patterns is disposed adjacent to the first side of the mother vernier pattern. A second plurality of dummy patterns is disposed adjacent to the second side of the mother vernier pattern. The first and second dummy patterns are configured to disperse intensity of exposure light.

### BRIEF DESCRIPTION OF THE DRAWINGS

FIG. 1 is a diagram illustrating an overlay vernier according to an embodiment of the present invention;

FIG. 2 is a diagram illustrating an overlay vernier according to an embodiment of the present invention;

FIG. 3 is a plane-view illustrating an overlay vernier mask according to an embodiment of the present invention;

FIG. 4 is a cross-sectional view illustrating an overlay vernier mask according to an embodiment of the present invention;

FIG. 5 is a diagram illustrating a photoresist pattern formed over a wafer with an overlay vernier mask according to an embodiment of the present invention; and

FIGS. 6a through 6d are cross-sectional views illustrating a method for forming an overlay vernier according to an embodiment of the present invention.

### DESCRIPTION OF EMBODIMENTS

The present invention relates to a semiconductor device including a metal layer. In an embodiment, a metal layer is formed with a sloped sidewall overlay vernier, i.e., an overlay vernier having a sloped sidewall. The sloped sidewall overlay vernier is formed with a bar type dummy pattern disposed adjacent to a bar type mother overlay vernier pattern to disperse the intensity of exposure light.

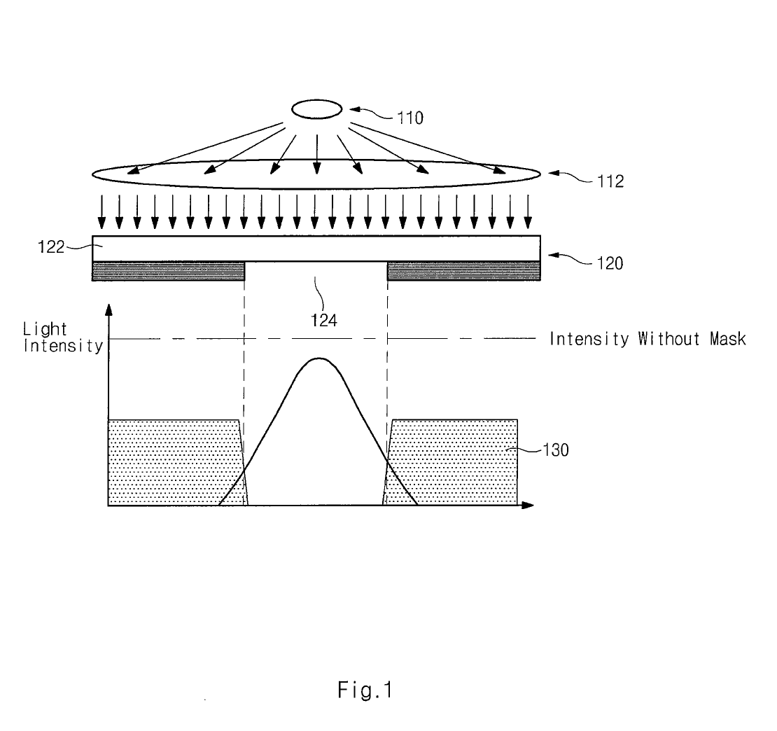

FIG. 1 is a diagram illustrating an overlay vernier according to an embodiment of the present invention. A light emitted from an exposure light source 110 is transmitted into an overlay vernier mask 120 through a lens 112. The light passed through the overlay vernier mask 120 is transmitted into a photoresist film formed over a wafer. A developing process is performed to form a photoresist pattern 130 having a sharp sidewall profile. The overlay vernier mask 120 includes a bar-type mother vernier pattern 124 over a transparent substrate 122.

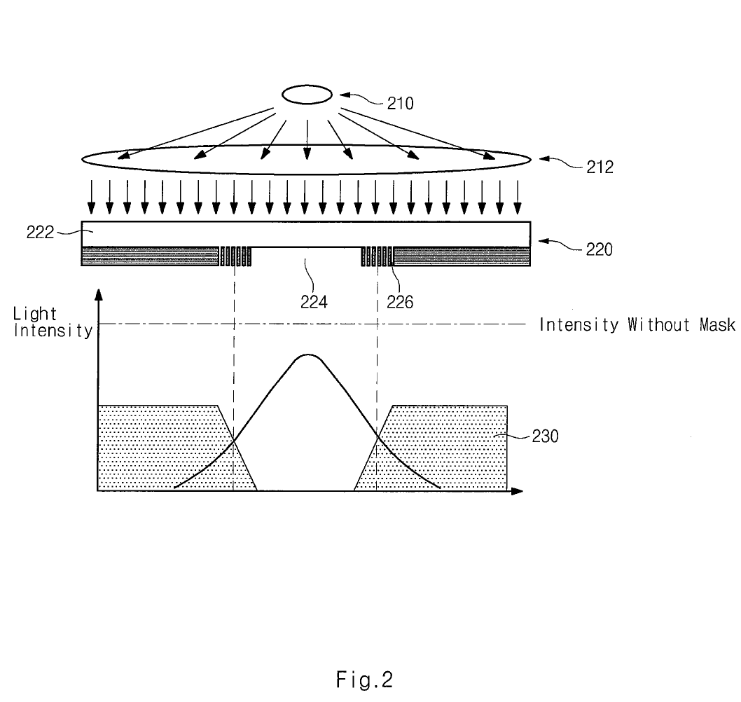

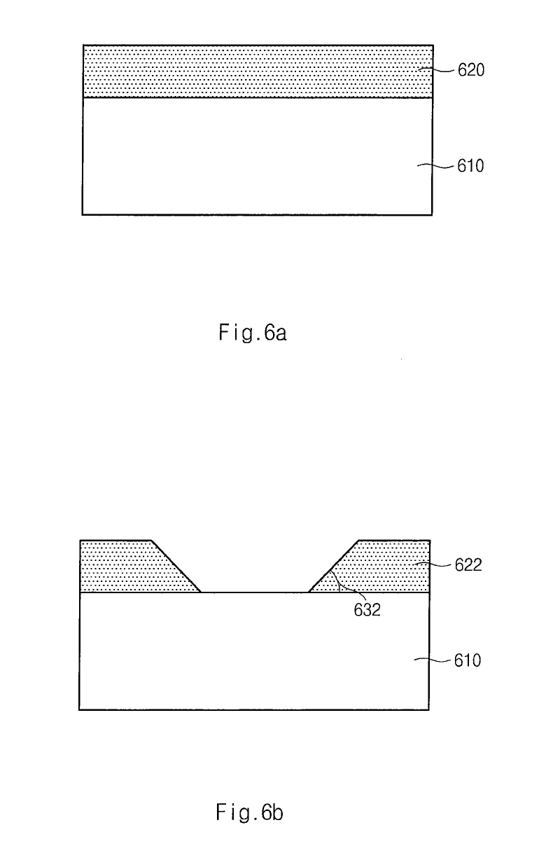

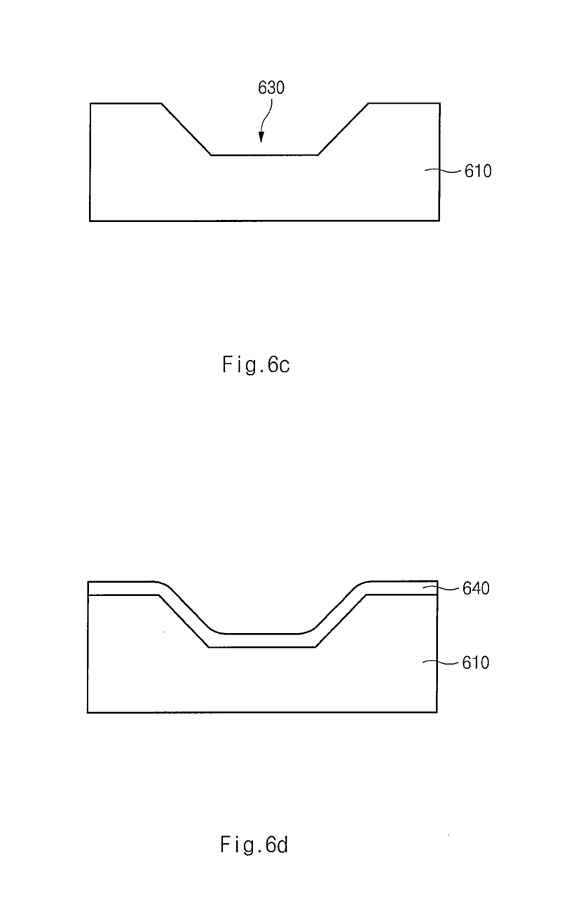

FIG. 2 is a diagram illustrating an overlay vernier according to an embodiment of the present invention. According to an embodiment of the present invention, an overlay vernier minimizes overlay misreading which may be generated when a metal layer is deposited using a sputtering apparatus. That is, a light emitted from an exposure light source 210 is transmitted into an overlay vernier mask 220. The light passed through the overlay vernier mask 220 is transmitted into a photoresist film formed over a wafer. A developing process is performed to form a photoresist pattern 230 having a sloped sidewall. An overlay vernier having a sloped sidewall is formed using the photoresist pattern 230. In the present embodiment, the overlay vernier (or mother vernier) is formed by etching a semiconductor substrate using the photoresist pattern (see FIG. 6c). A layer (child vernier) is formed over the mother, e.g., a metal layer, by sputtering. The metal particles ejected from the sputtering target tend to deposit over the sloped mother vernier at an oblique angle. The resulting metal layer, nevertheless, is deposited uniformly over the mother overlay vernier.

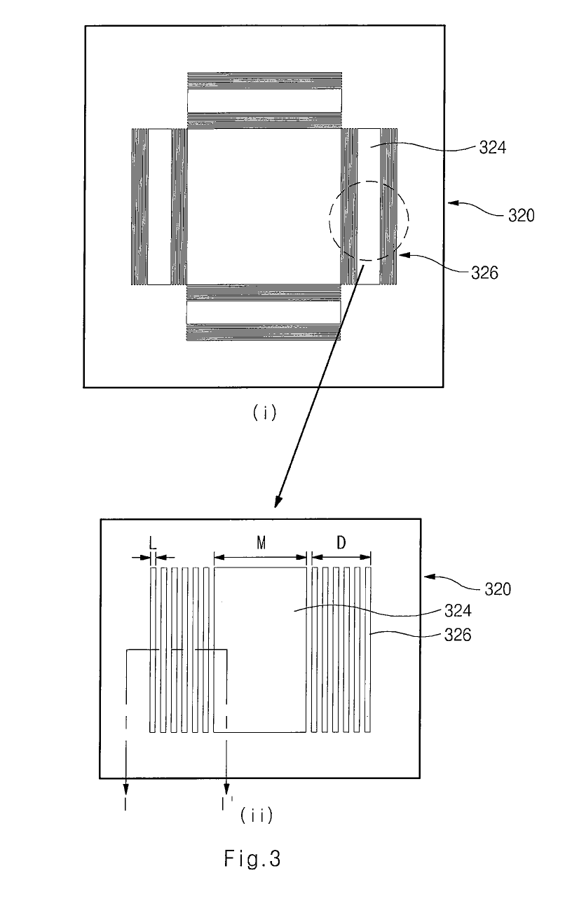

FIG. 3 is a plane-view illustrating an overlay vernier mask according to an embodiment of the present invention. FIG. 3(i) shows an overlay vernier mask 320 including a bar-type mother pattern 324, and FIG. 3(ii) shows the enlarged bar-type mother vernier pattern 324 of the dotted circle. The overlay vernier mask 320 includes the bar type mother vernier pattern 324 and a plurality of dummy patterns 326 formed on both sides of the mother vernier pattern 324 along the minor axis (or X-axis in FIG. 3) of the mother vernier pattern.

The dummy pattern 326 reduces the intensity of light passing through the mask 320 to form a sloped pattern over the wafer. The plurality of dummy patterns 326 are of a bar type, i.e., a pattern having an elongated shape with the length being significantly greater than the width. A line width D of the plurality of dummy patterns 326 formed on one side of the mother vernier pattern 324 is in a range of about 0.15˜0.35 of the line width M of the mother vernier pattern 324 (0.15M≦D≦0.35M). For example, when the line width M of the mother vernier pattern 324 is 2 μm, the line width of the plurality of dummy patterns 326 is in a range of about 0.1˜0.3 μm.

A line width L of the dummy pattern 326 is in a range of about 0.01˜0.02 of the line width M of the mother vernier pattern 324 (0.01M≦L≦0.02M). For example, when the line width M of the mother vernier pattern 324 is 2 μm, the line width L of the dummy pattern 326 is in a range of about 20˜40 nm.

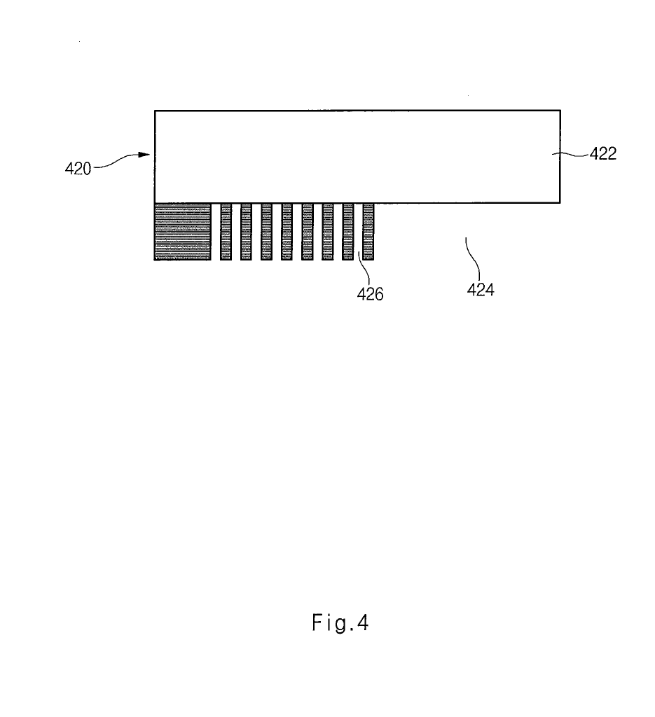

FIG. 4 is a cross-sectional view illustrating an overlay vernier mask according to an embodiment of the present invention. FIG. 4 is a cross-sectional view taken along I-I′ of FIG. 3(ii). An overlay vernier mask 420 is a Box-in-Bar type overlay vernier. The overlay vernier mask 420 includes a mother vernier pattern 424 and a plurality of dummy patterns 426 disposed adjacent to the mother vernier pattern 424. The dummy pattern 426 reduces the intensity of light passing through a mask to form a sloped pattern over the wafer.

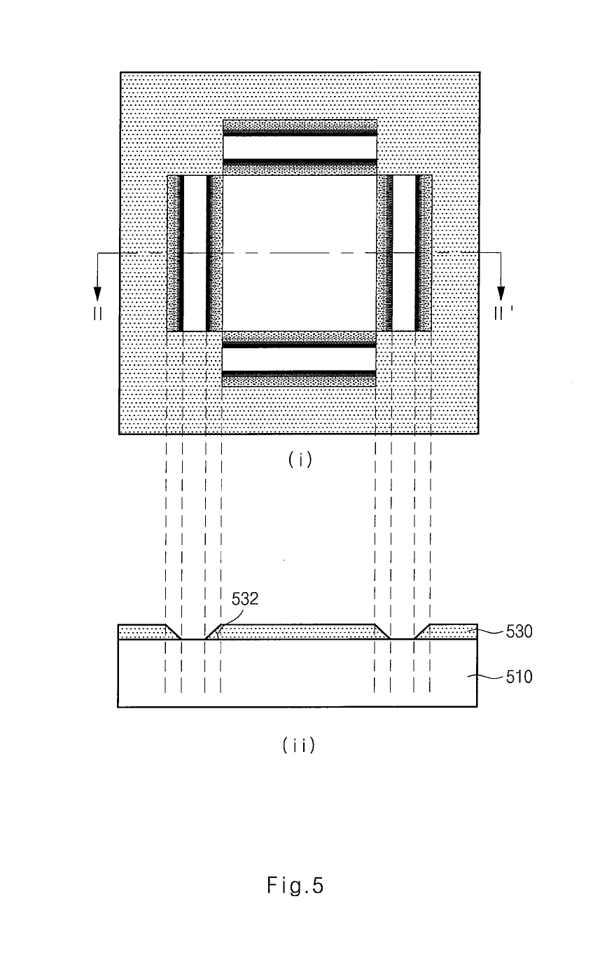

FIG. 5 is a diagram illustrating a photoresist pattern formed over a wafer with an overlay vernier mask according to an embodiment of the present invention. FIG. 5(ii) is a cross-sectional view illustrating a photoresist pattern taken along II-II′ of FIG. 5(i). A photoresist film (not shown) formed over a semiconductor substrate 510 is exposed and developed using the overlay vernier mask 320 of FIG. 3 to form a photoresist pattern 530 having a sloped profile. A sloped angle 532 of the photoresist pattern 530 is in a range of about 30˜60°. The overlay vernier is used when a metal layer is deposited using a sputtering apparatus.

FIGS. 6a to 6d are cross-sectional views illustrating a method for forming an overlay vernier according to an embodiment of the present invention. FIGS. 6a to 6d are cross-sectional views taken along II-II′ of FIG. 5. A photoresist film 620 is formed over a semiconductor substrate 610 including a scribe lane. The photoresist film 620 is exposed and developed using a Box-in-Bar type overlay vernier mask including the dummy pattern 326 formed on both sides of the mother vernier pattern along the minor axis of the mother vernier pattern 324, thereby obtaining a photoresist pattern 622 having a sloped profile (FIG. 6b). The semiconductor substrate 610 is etched using the photoresist pattern 622 as an etching mask to form a mother vernier 630 having a sloped profile (FIG. 6c). The photoresist pattern 622 is removed. A metal layer 640 is formed over the semiconductor substrate 610 including the mother vernier 630 of FIG. 6c. In the present embodiment, the mother vernier 630 is a silicon substrate, but the mother vernier may be a layer formed over a substrate in other embodiments.

A sloped angle 632 of the mother vernier 630 is in a range of about 30˜60°. The mother vernier 630 is used when a metal layer is deposited using a sputtering apparatus.

As described above, a semiconductor device and a method for fabricating the same according to an embodiment of the present invention prevent asymmetric deposition when a metal layer is deposited using a sputtering apparatus, thereby improving overlay misreading. Also, a subsequent process margin is improved to increase yield of devices.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. An overlay vernier mask comprising:
a transparent substrate;
a bar-type mother vernier pattern disposed over the transparent substrate, the mother vernier pattern defining a first side and a second side, the first side being on an opposing side of the second side;
a first plurality of dummy patterns disposed adjacent to the first side of the mother vernier pattern; and
a second plurality of dummy patterns disposed adjacent to the second side of the mother vernier pattern,
wherein the first and second dummy patterns are configured to disperse intensity of exposure light.

2. The overlay vernier mask of claim 1, wherein the first and second dummy patterns are bar type patterns formed on a side of the mother vernier pattern along a minor axis of the mother vernier pattern.

3. The overlay vernier mask of claim 2, wherein the first and second dummy patterns have substantially the same length as that of the mother vernier pattern.

4. The overlay vernier mask of claim 3, wherein the overlay vernier mask is a Box-in-Bar type.

5. The overlay vernier mask of claim 2, wherein the first and second dummy patterns have a line width D, and the mother vernier pattern has a line width M, where 0.15M≦D≦0.35M.

6. The overlay vernier mask of claim 1, wherein the first and second dummy patterns have a line width L, and the mother vernier pattern has a line width M, where 0.01M≦L≦0.02M.

7. A semiconductor substrate, comprising:
a core region wherein transistors are defined;
a scribe lane provided at a periphery of the core region; and
a bar-type mother vernier formed in the scribe lane, the mother vernier having a sloped profile.

8. The substrate of claim 7, wherein the sloped profile of the mother vernier defines an angle of about 30˜60°.

9. The substrate of claim 7, further comprising: a metal layer disposed over the core region and the mother vernier defined at the scribe lane, wherein the metal layer is formed by a sputtering method.

10. A method for forming an overlay vernier having a Box-in-Bar type overlay vernier, the method comprising:
providing a semiconductor substrate defining a scribe lane;
forming a photoresist film over a material;
exposing the photoresist film by using an overlay vernier mask including a mother vernier pattern and a plurality of dummy vernier patterns to form a photoresist pattern having a sloped profile, the dummy vernier patterns provided adjacent to the mother vernier pattern; and
etching the material in the scribe lane by using the photoresist pattern as an etch mask to form a mother overlay vernier having a sloped profile at the scribe lane.

11. The method of claim 10, wherein the dummy patterns are bar type patterns formed on at least one side of the mother vernier pattern along a minor axis of the mother vernier pattern, wherein the material is the semiconductor substrate.

12. The method of claim 11, wherein a line width D of the dummy patterns is in a range of about 0.15˜0.35 of a line width M of the mother veriner pattern.

13. The method of claim 11, wherein a line width L of the dummy pattern is in a range of about 0.01˜0.02 of a line width M of the mother vernier pattern.

14. The method of claim 10, wherein the sloped profile of the mother vernier defines an angle of about 30˜60°.

15. A method for fabricating a semiconductor device, the method comprising:
providing a semiconductor substrate including a scribe lane;
forming a photoresist film over the semiconductor substrate;
exposing the photoresist film by using an overlay vernier mask including a plurality of dummy patterns to form a photoresist pattern having a sloped profile at the scribe lane;
etching the semiconductor substrate at the scribe lane by using the photoresist pattern as an etching mask to form a mother vernier having a sloped profile;
removing the photoresist pattern; and
performing a sputtering process to form a metal layer over the mother vernier of the semiconductor substrate.
